(19) United States
(12) Patent Application Publication
(10) Pub. No.: US 2023/0307376 A1
(43) Pub. Date: Sep. 28, 2023

(54) Power Semiconductor Module with Two Opposite Half-Bridges

(71) Applicant: ZF Friedrichshafen AG, Friedrichshafen (DE)

(72) Inventor: Wei Liu, Friedrichshafen (DE)

(21) Appl. No.: 18/188,555

(22) Filed: Mar. 23, 2023

(30) Foreign Application Priority Data
Mar. 24, 2022 (DE) 10 2022 202 898.8

(51) Int. Cl. H01L 23/538; H01L 23/373; H01L 23/495; H01L 25/07; H01L 23/00; H05K 1/02

(52) U.S. Cl. CPC H01L 23/5385; H01L 23/3735; H01L 23/49562; H01L 23/5384; H01L 25/072; H01L 24/05; H05K 1/0298; H01L 2224/04105

(57) ABSTRACT

A power semiconductor module (10) includes: a multilayer circuit board (18); a first semiconductor chip (T1) and a second semiconductor chip (T2) bonded to a first outer conducting layer (20a); a third semiconductor chip (T3) and a fourth semiconductor chip (T4) bonded to a second outer conducting layer (20b); a first substrate (42a) attached to the first semiconductor chip (T1) and the second semiconductor chip (T2); and a second substrate (42b) attached to the third semiconductor chip (T3) and the fourth semiconductor chip (T4). The first outer conducting layer (20a) is structured into a first DC+ area (26a), a first AC area (28a) and a first DC− area (30a) that interconnect the first semiconductor chip (T1) and the second semiconductor chip (T2) into a half-bridge. The second outer conducting layer (20b) is structured into a second DC+ area (26b), a second AC area (28b) and a second DC− area (30b), which interconnect the third semiconductor chip (T3) and the fourth semiconductor chip (T4) into a half-bridge. The first DC− area (30a) is connected via the first substrate (42) and a traversing conducting post (50) with an intermediate DC− area (32) of the intermediate conducting layer (24) and the second DC− area (30b) is connected via the second substrate (42b) and the traversing conducting post (50) with the intermediate DC− area (32). The traversing conducting post (50) runs through the multilayer circuit (18) between the first substrate (42a) and the second substrate (42b).

### CROSS-REFERENCE TO RELATED APPLICATION

The present application is related and has right of priority to German Patent Application No. 102022202898.8 filed on Mar. 24, 2022, which is incorporated by reference in its entirety for all purposes.

### FIELD OF THE INVENTION

The invention relates generally to a power semiconductor module.

### BACKGROUND

In automotive applications with electrical drives, such as electrical cars and trucks, half-bridge modules are used for assembling inverters, which generate the AC current for driving an electrical motor, from a DC current, which may be provided by an electrical battery. Currently, such half-bridge modules include silicon (Si) semiconductors. However, due to their higher operation voltages and the possible higher switching frequencies, which may result in lower losses and a more efficient application of the half-bridge modules, it is also considered to use high bandgap semiconductors.

Such power semiconductor modules based on high bandgap semiconductors may benefit from new module designs, since higher switching frequencies usually result in different and/or higher electromagnetic radiation and losses. Also, an operation at higher voltages may need better local cooling capabilities.

### SUMMARY OF THE INVENTION

Example aspects of the present invention provide a power semiconductor module

A first example aspect of the invention relates to a power semiconductor module. A power semiconductor module is a device for mechanically and electrically interconnecting power semiconductor chips. Here and in the following, the term “power” refers to devices and elements adapted for processing voltages of more than one hundred volts (100 V) and/or more than ten amps (10 A).

According to an example embodiment of the invention, the power semiconductor module includes a multilayer circuit board with a first outer conducting layer, a first isolating or insulation layer, an intermediate conducting layer, a second isolating or insulation layer and a second outer conducting layer. These layers may be arranged in this order in a direction orthogonal to an extension direction of the layers. The first isolating layer is sandwiched between the first outer conducting layer and the intermediate conducting layer. The second isolating layer is sandwiched between the second outer conducting layer and the intermediate conducting layer. The conducting layers may be made of metal, such as copper, and/or may be metallization layers. The isolating layers may be made of plastics and/or ceramics. The multilayer circuit board may be a PCB (printed circuit board), a DBC (direct bonded copper) substrate or an IMS (insulated metal substrate).

According to an example embodiment of the invention, the power semiconductor module includes a first semiconductor chip and a second semiconductor chip, which are bonded to the first outer conducting layer and a third semiconductor chip and a fourth semiconductor chip, which are bonded to the second outer conducting layer. Such semiconductor chips may have a plastics housing, which encloses a die made of a semiconductor material, which provides the functionality of the chip. The semiconductor chips may include controllable switches, such as transistors and/or thyristors. In particular, the semiconductor chips may include HEMTs. Every semiconductor chip may provide two power electrodes to be supplied with the main current through the device (such as drain and source electrodes, or emitter and collector electrodes) and a control electrode for switching the main current (such as a gate electrode or a base electrode).

Here and in the following, bonding may refer to a process for electrically and mechanically connecting two metallic elements, such as soldering, welding and sintering.

According to an example embodiment of the invention, the power semiconductor module includes a first substrate attached to the first semiconductor chip and the second semiconductor chip, such that the first semiconductor chip and the second semiconductor chip are arranged between the first substrate and the multilayer circuit board. Furthermore, the power semiconductor module includes a second substrate attached to the third semiconductor chip and the fourth semiconductor chip, such that the third semiconductor chip and the fourth semiconductor chip are arranged between the second substrate and the multilayer circuit board. The first substrate may include a first conducting layer and the second substrate may include a second conducting layer, which conducting layers are used for electrically interconnecting the intermediate conducting layer with DC− areas of the outer conducting layer of the multilayer circuit board. The first substrate and/or the second substrate may be a PCB (printed circuit board), a DBC (direct bonded copper) substrate or an IMS (insulated metal substrate).

According to an example embodiment of the invention, wherein the first outer conducting layer of the multilayer circuit board is structured into a first positive direct current (DC+) area, a first alternating current (AC) area and a first negative direct current (DC−) area, which interconnect the first semiconductor chip and the second semiconductor chip into a half-bridge. Furthermore, the second outer conducting layer of the multilayer circuit board is structured into a second positive direct current (DC+) area, a second alternating current (AC) area and a second negative direction current (DC−) area, which are separated from each other on the second isolating layer and which interconnect the third semiconductor chip and the fourth semiconductor chip into a half-bridge. The first DC+ area, the first AC area and the first DC− area may be separated from each other on the first isolating layer. The second DC+ area, the second AC area and the second DC− area may be separated from each other on the second isolating layer. “separated from each other on the isolating layer” may mean that the corresponding components are electrically isolated from each other, when the respective semiconductor chips are not present, i.e. bonded to them.

It also may be that the first outer conducting layer and/or the second outer conducting layer includes a control electrode area, which is separated from the other areas. Control electrodes of the semiconductor chips may be bonded to the control electrode areas. The power electrodes and optionally the control electrode of a semiconductor chip may be provided on the same side of the semiconductor chip.

In this way, the first semiconductor chip and the second semiconductor chip are connected into a half-bridge and the third semiconductor chip and the fourth semiconductor chip are connected into a half-bridge. A half-bridge is a circuit, in which the corresponding two semiconductor chips, each of which includes a semiconductor switch, are series connected.

According to an example embodiment of the invention, the first DC− area is connected via the first substrate and a traversing conducting post with the intermediate conducting layer and the second DC− area is connected via the second substrate and the traversing conducting post with the intermediate conducting layer. The traversing conducting post runs through the multilayer circuit, i.e. traverses the multiplayer circuit, between the first substrate and the second substrate. In particular, the traversing conducting post is connected with an intermediate DC− area provided by the intermediate conducting layer.

Since the DC− areas are connected to the intermediate layer, which conducts the current through the DC− side of the power semiconductor module between the semiconductor chips and their electrical interconnection, the power semiconductor module has a low inductance of the power conductor loop. This power conductor loop is further reduced by guiding the current above the second and fourth semiconductor chip through conducting layers of the first substrate and the second substrate. This results in a lower stray inductance of power conductor loops formed by the power semiconductor module together with further electrical components to which the power semiconductor module is connected. This may be beneficial, when the power semiconductor chips are switched with higher frequencies as ordinary devices, which may be the case for chips based on a wide bandgap material.

Furthermore, a symmetric arrangement of the first semiconductor chip and the second semiconductor chip with respect to the third semiconductor chip and the fourth semiconductor chip results in an even current distribution inside the power semiconductor module. The symmetric arrangement may be mirror symmetric. The first outer conducting layer and the second outer conducting layer may be arranged (mirror) symmetric. The first substrate and the second substrate may be arranged (mirror) symmetric.

The DC− current runs through the first substrate and the second substrate, to which cooling elements may be attached directly. Thus, the current path through the module may be cooled more efficiently.

Due to the half-bridges on each side of the multilayer circuit board, the power semiconductor module provides a high power density. The arrangement of the components of the power semiconductor module results in a compact design. The usually substantially cuboid-shaped space occupied by the power semiconductor module may be designed to be more like a cube than a flat box. This may result in more freedom for assembling the semiconductor module into an inverter.

According to an example embodiment of the invention, the traversing conducting post is arranged between the first semiconductor chip and the second semiconductor chip and/or is arranged between the third semiconductor chip and the fourth semiconductor chip. The intermediate DC− area may solely be arranged between the first semiconductor chip and third semiconductor chip. The intermediate DC− area may be connected at a side to the traversing conducting post.

According to an example embodiment of the invention, the traversing conducting post is connected to the intermediate DC− area of the intermediate conducting layer inside the multilayer circuit board. For example, the traversing conducting post may be or may include a through via of the multilayer circuit board, which is connected inside the multilayer circuit board, in particular between the two isolating layers, with the intermediate DC− area.

According to an example embodiment of the invention, the first substrate includes a conducting layer and an isolating or insulating layer, wherein the conducting layer of the first substrate is structured to provide a third negative direct current (DC−) area which is connected to the first DC− area of multilayer circuit board and the traversing conducting post. Analogously, the second substrate includes a conducting layer and an isolating layer, wherein the conducting layer of the second substrate is structured to provide a fourth negative direct current (DC−) area which is connected to the second DC− area of multilayer circuit board and the traversing conducting post. The conduction layers may be made of metal. A part of the conducting layers of the first substrate and the second substrate may be used for connecting the respective DC− areas with the traversing conducting post. The conducting layers of the first substrate and the second substrate may be arranged to face the semiconductor chips.

According to an example embodiment of the invention, the traversing conducting post is connected to a third negative direct current (DC−) area of the first substrate, which third DC− area is connected to the first DC− area, wherein the first DC− area and the third DC− area are connected via a first conducting post. Analogously, the traversing conducting post is connected to a fourth negative direct current (DC−) area of the second substrate, which fourth DC− area is connected to the second DC− area, wherein the second DC− area and the fourth DC− area are connected via a second conducting post. The first and second conducting posts may be made of metal pins and/or blocks, which are bonded to the multilayer circuit board and the first substrate and the second substrate, respectively.

According to an example embodiment of the invention, the first conducting post is arranged besides the second semiconductor chip opposite to the traversing conducting post. Analogously, the second conducting post is arranged besides the fourth semiconductor chip opposite to the traversing conducting post. Thus, the DC− current may run around the second semiconductor chip via the first conducting post, the third DC− area of the first substrate and the traversing conducting post. Also, the DC− current may run around the fourth semiconductor chip via the second conducting post, the fourth DC− area of the second substrate and the traversing conducting post.

According to an example embodiment of the invention, the intermediate DC− area is arranged between the first DC+ area and the second DC+ area. The DC− current may further be guided between the first semiconductor chip and the second semiconductor chip.

According to an example embodiment of the invention, the intermediate DC− area is arranged between the first AC area and the second AC area. It may be that at least partially, the intermediate DC− area is also arranged between the AC areas.

According to an example embodiment of the invention, the intermediate DC− area is arranged between the first semiconductor chip and the third semiconductor chip. As already mentioned, the DC− current may be guided between the first semiconductor chip and the second semiconductor chip.

According to an example embodiment of the invention, the first AC area and the second AC area are connected to an intermediate AC area of the intermediate conducting layer. The intermediate conducting layer may be structured into the intermediate DC− area and the intermediate AC area. The intermediate AC area may be arranged between the first DC− area and the second DC− area. The intermediate AC area may be arranged between the second semiconductor chip and the fourth semiconductor chip. The AC current may be guided between the third semiconductor chip and the fourth semiconductor chip as well as between the first DC− area and the second DC− area.

According to an example embodiment of the invention, an AC terminal is connected to the intermediate AC area. The AC terminal may be provided on a side of the power semiconductor module, which is opposite to a side, where DC terminals are arranged.

It may be that the first AC area and the second AC area are connected, for example via an AC terminal and/or via the intermediate AC area. It also may be that the first DC+ area and the second DC+ area are connected with each other, for example, via a DC− terminal. In such a way, the two half-bridges formed by the first and second semiconductor chips as well as third and fourth semiconductor chips are paralleled in the power semiconductor module.

According to an example embodiment of the invention, a DC+ terminal is connected to the DC+ area of the first outer conducting layer and to the DC+ area of the second outer conducting layer. Also, a DC− terminal may be connected to the intermediate conducting layer and in particular to the intermediate DC− area. The terminals, i.e. the DC terminals and/or the AC terminals, may be parts of the power semiconductor module, where the power semiconductor module is electrically connected to further devices.

The terminals may be connected to the multilayer circuit board, such that the two half-bridges formed by the semiconductor chips are connected in parallel with respect to DC+, DC− and AC. Such half-bridges may be used for generating the phase of an AC current from a DC current. The power semiconductor module also may be seen as a half-bridge module.

According to an example embodiment of the invention, the DC+ terminal and the DC− terminal are arranged at the same first side of the power semiconductor module. An AC terminal connected to the first AC area and the second AC area, for example via the intermediate AC area, is arranged on a second side of the power semiconductor module, which second side is opposite to the first side. The layers of the multilayer circuit board may extend substantially parallel to a plane. Also, the sides of the multilayer circuit board to which the semiconductor chips are bonded extend in this plane. The small sides of the multilayer circuit board are located at a border of the multilayer circuit board, which may have a substantially rectangular shape. The DC+ terminal and the DC− terminal may be arranged at the same small side. This may reduce the size of the power conductor loops.

According to an example embodiment of the invention, the first semiconductor chip and the third semiconductor chip are arranged opposite to each other with respect to the multilayer circuit board. Analogously, the second semiconductor chip and the fourth semiconductor chip are arranged opposite to each other with respect to the multilayer circuit board. With respect to a view direction onto the plane of the multilayer circuit board, the first (or second) semiconductor chip and the third (or fourth) semiconductor chip may overlap each other substantially completely. As already mentioned, the semiconductor chip may be arranged mirror symmetric with respect to a middle plane of the multilayer circuit board.

According to an example embodiment of the invention, the first DC+ area and the second DC+ area are arranged opposite to each other with respect to the multilayer circuit board. Also, the first AC area and the second AC area may be arranged opposite to each other with respect to the multilayer circuit board. Furthermore, the first DC− area and the second DC− area may be arranged opposite to each other with respect to the multilayer circuit board. It also may be that the third DC− area and the fourth DC-area are arranged opposite to each other with respect to the multilayer circuit board. All these areas may be arranged mirror symmetric with respect to a middle plane of the multilayer circuit board. With respect to a view direction onto the plane of the multilayer circuit board, the DC+ areas, AC areas and/or respective DC− areas may overlap each other substantially completely.

According to an example embodiment of the invention, the first semiconductor chip and the second semiconductor chip are arranged in a row along the first DC+ area, the first AC area and the first DC− area. Analogously, the third semiconductor chip and the fourth semiconductor chip are arranged in a row along the second DC+ area, the second AC area and the second DC− area.

According to an example embodiment of the invention, wherein a first cooling element is attached to a backside of the first substrate opposite to the multilayer circuit board and/or a second cooling element is attached to a backside of the second substrate opposite to the multilayer circuit board. The backside of a semiconductor chip may be located opposite to a power electrodes side with the power electrodes of the semiconductor chip. The semiconductor chips may have all its electrodes on a first side, i.e. the power electrodes side. The second side or backside may be cooled with the respective cooling element. Such cooling elements may have radiators or heat sinks and/or may be water cooled and/or air cooled.

According to an example embodiment of the invention, spacers are arranged between the multilayer circuit board and the first substrate and the second substrate. The spacers may be used for mechanically supporting the first substrate and the second substrate on the multilayer circuit board. The spacers also may be used for thermally connecting the first substrate and the first cooling element and the second substrate and the second cooling element to the multilayer circuit board. Such spacers may be made of an electrically insulating material and/or thermally conducting material. The spacers may be used for directly cooling the DC+ area, the AC area and/or the DC− areas provided on the multilayer circuit board. In such a way, it may be avoided that these areas, which may be directly connected to the power electrode side of the semiconductor chips, become too hot.

According to an example embodiment of the invention, each of the first semiconductor chip, the second semiconductor chip, the third semiconductor chip and the fourth semiconductor chip has power electrodes on a side facing the multilayer circuit board. The power electrode side of the respective semiconductor chip may be bonded to the respective conducting layer of the multilayer circuit board.

According to an example embodiment of the invention, the first semiconductor chip, the second semiconductor chip, the third semiconductor chip and the fourth semiconductor chip are based on a wide bandgap semiconductor material, for example GaN (gallium nitride) or SiC (silicon carbide). The die of each semiconductor chip may be made of a wide bandgap material. Such semiconductor chips allow for higher switching frequencies and/or higher operation voltages.

### BRIEF DESCRIPTION OF THE DRAWINGS

These and other aspects of the invention will be apparent from and elucidated with reference to the embodiments described hereinafter. Below, embodiments of the present invention are described in more detail with reference to the attached drawings.

FIG. 1 shows a circuit diagram of a power semiconductor module according to an example embodiment of the invention.

FIG. 2 shows a schematic cross-sectional view of a power semiconductor module according to an example embodiment of the invention.

The reference symbols used in the drawings, and their meanings, are listed in summary form in the list of reference symbols below. In principle, identical parts are provided with the same reference symbols in the figures.

### DETAILED DESCRIPTION

Reference will now be made to embodiments of the invention, one or more examples of which are shown in the drawings. Each embodiment is provided by way of explanation of the invention, and not as a limitation of the invention. For example, features illustrated or described as part of one embodiment can be combined with another embodiment to yield still another embodiment. It is intended that the present invention include these and other modifications and variations to the embodiments described herein.

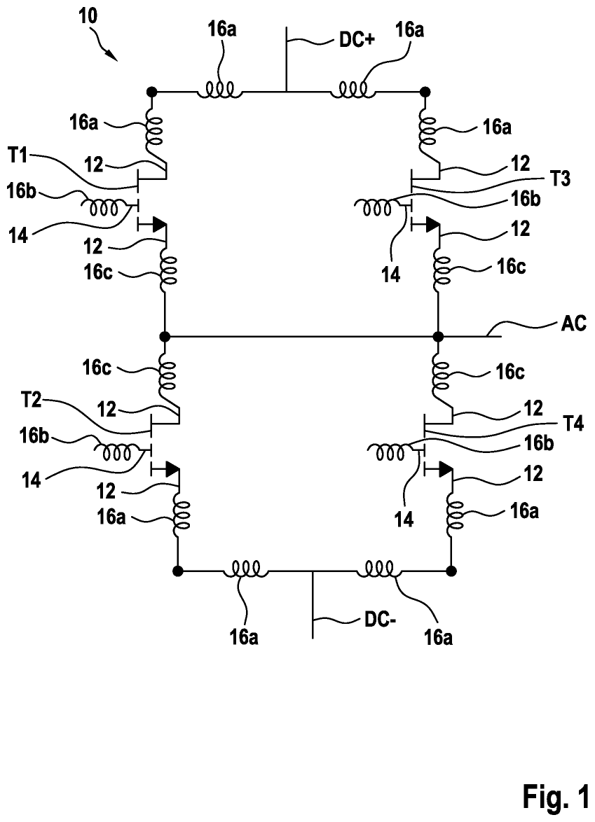

FIG. 1 shows a circuit diagram of a power semiconductor module 10, which includes four power semiconductor chips T1, T2, T3 and T4, which may be GaN or SiC transistors. Such wide bandgap semiconductor chips T1, T2, T3, T4 provide the possibility to operate the power semiconductor module 10 with higher voltages and/or higher switching frequencies.

The semiconductor chips T1, T2 are connected in series to form a first half-bridge and the semiconductor chips T3, T4 are connected in series to form a second half-bridge. The two half-bridges are connected in series at a DC+ terminal, a DC− terminal and an AC terminal. Each of the power semiconductor chips T1, T2, T3, T4 has two power electrodes 12 and a control electrode 14. The series connection of the power semiconductor chips T1, T2, T3, T4 is via the power electrodes 12.

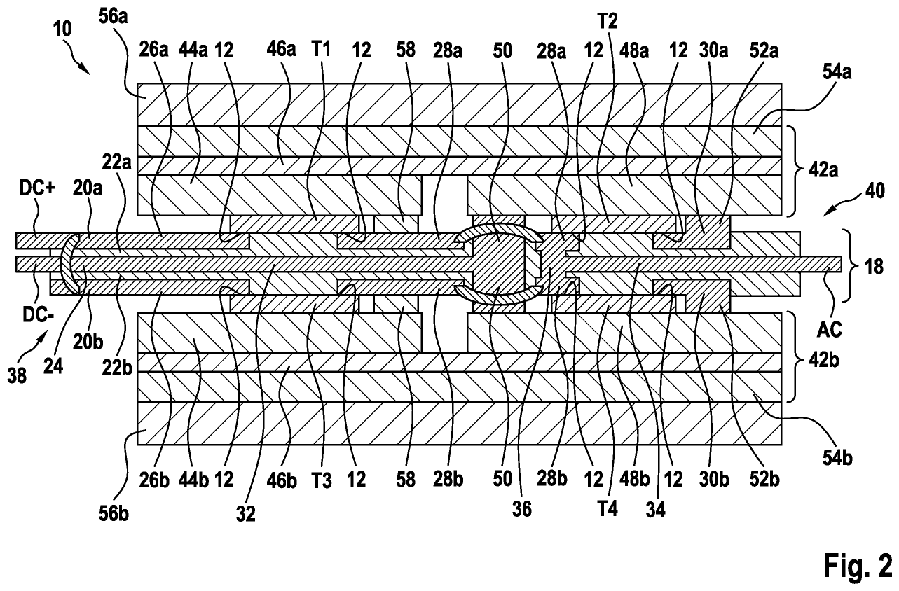

FIG. 1 furthermore shows stray and/or parasitic inductances 16a, 16b, 16c which can be reduced with the design such as shown in FIG. 2.

FIG. 2 shows a power semiconductor module 10 with a circuit diagram such as shown in FIG. 1. Same parts in FIG. 1 and FIG. 2 are depicted with the same reference numerals.

The power semiconductor module 10 includes a multilayer circuit board 18, which in this order includes a first outer conducting layer 20a, a first isolating layer 22a, an intermediate conducting layer 24, a second isolating layer 22b and a second outer conducting layer 20b. The multilayer circuit board 18 may be provided by a printed circuit board, by a DBC (direct bonded copper) substrate or IMS (insulated metal substrate). The conducting layers 20a, 20b, 24 may be metallization layers, such as copper layers. The isolating layers 22a, 22b may be made of plastics or ceramics. It also may be that the multilayer circuit board 18 includes more than five layers.

The multilayer circuit board 18 defines a plane, to which all the layers of the multilayer circuit board 18 and also the layers of the first and second substrate (see below) run in parallel. This plane may be seen as main extension plane of the power semiconductor module 10.

The first outer conducting layer 20a is structured to provide a first DC+ area 26a, a first AC area 28a and a first DC− area 30a, which are separated from each other on the first isolating layer 22a. The second outer conducting layer 20b is structured to provide a second DC+ area 26b, a second AC area 28b and a second DC− area 30b, which are separated from each other on the second isolating layer 22b. These areas may be seen as conductor paths and/or tracks, which provide a part of the electric circuitry of the power semiconductor module 10, such as shown in FIG. 1.

The semiconductor chip T1 is bonded with an electrode side to the DC+ area 26a and the AC area 28a of the conducting layer 20a, in particular such that one power electrode 12 is bonded to the DC+ area 26a and that the other one power electrode 12 is bonded to the AC area 28a. The semiconductor chip T2 is bonded with an electrode side to the AC area 28a and the DC− area 30a of the conducting layer 20a, in particular such that one power electrode 12 is bonded to the AC area 28a and that the other one power electrode 12 is bonded to the DC− area 30a.

The semiconductor chip T3 is bonded with an electrode side to the DC+ area 26b and the AC area 28b of the conducting layer 20b, in particular such that one power electrode 12 is bonded to the DC+ area 26b and that the other one power electrode 12 is bonded to the AC area 28b. The semiconductor chip T4 is bonded with an electrode side to the AC area 28b and the DC− area 30b of the conducting layer 20b, in particular such that one power electrode 12 is bonded to the AC area 28b and that the other one power electrode 12 is bonded to the DC− area 30b.

As mentioned above, such power electrodes 12 may include drain, source, emitter and collector electrodes.

Each of the semiconductor chips T1, T2, T3, T4 has a substantial cuboid body with a height substantially (such as at least five (5) times) smaller than a width and a length. The cuboid bodies may be oriented in parallel to the plane defined by the multilayer circuit board 18. On one side, which may be seen as the front side or power electrode side, the power electrodes 12 are arranged. The opposite side may be seen as the backside of the respective semiconductor chip T1, T2, T3, T4. On the power electrode side, also a control electrode may be arranged.

The first semiconductor chip T1 and the second semiconductor chip T2 are arranged in a row along the DC+ area 26a, the AC area 28a and the DC− area 30a of the first outer conducting layer 20a. The third semiconductor chip T3 and the fourth semiconductor chip T4 are arranged in a row along the DC+ area 26b, the AC area 28b and the DC− area 30b of the second outer conducting layer 20b. The semiconductor chips T1 and T2 are electrically connected via the areas 26a, 28a, 30a into a first half-bridge and the semiconductor chips T3 and T4 are electrically connected via the areas 26b, 28b, 30b into a second half-bridge.

As indicated in FIG. 2, the DC+ areas 26a and 26b may be interconnected with each other. For example, this may be done with one or more through vias (not shown), which run through the intermediate layer 24 without being connected to the intermediate layer 24.

The first semiconductor chip T1 and the third semiconductor chip T3 are arranged opposite to each other with respect to the multilayer circuit board 18. Also, the second semiconductor chip T2 and the fourth semiconductor T4 chip are arranged opposite to each other with respect to the multilayer circuit board 18. With respect to a view direction onto the multilayer circuit board 18 and/or onto the plane defined by the multilayer circuit board 18, the chips T1 and T2 as well as the chips T3 and T4 substantially overlap each other.

The same applies to the areas 26a, 26b, 28a, 28b, 30a, 30b: The DC+ area 26a of the first outer conducting layer 20a and the DC+ area 26b of the second outer conducting layer 20b are arranged opposite to each other with respect to the multilayer circuit board 18. The AC area 28a of the first outer conducting layer 20a and the AC area 28b of the second outer conducting layer 20b are arranged opposite to each other with respect to the multilayer circuit board 18. The DC− area 30a of the first outer conducting layer 20a and the DC− area 30b of the second outer conducting layer 20b are arranged opposite to each other with respect to the multilayer circuit board 18. With respect to a view direction onto the multilayer circuit board 18 and/or onto the plane defined by the multilayer circuit board 18, the areas 26a, 26b and/or 28a, 28b and/or 30a, 30b, which are arranged opposite to each other, substantially overlap each other.

The intermediate layer 24 is structured into an intermediate DC− area 32 and an intermediate AC area 34. The intermediate DC− area 32 is arranged between the first DC+ area 26a and the second DC+ area 26b. Also, the intermediate DC− area 32 is arranged between the first AC area 28a and the second AC area 28b and/or the intermediate DC− area 32 is arranged between the first semiconductor chip T1 and the third semiconductor chip T3.

The AC areas 28a, 28b may be interconnected with each other. This may be done with a through via 36 which runs through the intermediate layer 24 and is connected to the intermediate layer 24. The AC area 28a and the AC area 28b are connected to an intermediate AC area 34 of the intermediate conducting layer 24. The intermediate AC area 34 is arranged between the first DC− area 30a and the second DC− area 30b and/or the intermediate AC area 34 is arranged between the second semiconductor chip T2 and the fourth semiconductor chip T4.

A DC+ terminal may be connected to the first DC+ area 26a and the second DC+ area 26b and a DC− terminal may be connected to the intermediate DC− area 32. The DC+ terminal may be provided by a part of the conducting layers 20a and/or 20b, which part may protrude from the multilayer circuit board 18. It also is possible that the DC+ terminal is a conducting plate or post bonded to the conducting layers 20a and/or 20b.

An AC terminal is connected to the intermediate AC area 34. The AC terminal may be provided by a part of the intermediate conducting layer 24, which part may protrude from the multilayer circuit board 18. It also is possible that the AC terminal is a conducting plate or post bonded to the intermediate conducting layer 24.

The DC+ terminal and the DC− terminal are arranged at the same first side 38 of the power semiconductor module 10. The AC terminal is arranged on a second side 40 of the power semiconductor module 10, which second side 40 is opposite to the first side 38. The small sides 38, 40 of the multilayer circuit board 18 may be defined as sides of the multilayer circuit board 18, which run substantially orthogonal to the plane defined by the multilayer circuit board 18. From the point of view in FIG. 2, the small sides 38, 40 are left and right with respect to the multilayer circuit board 18.

The power semiconductor module 10 furthermore includes a first substrate 42a attached, for example bonded to the first semiconductor chip T1 and the second semiconductor chip T2, and a second substrate 42b attached, for example bonded, to the third semiconductor chip T3 and the fourth semiconductor chip T4.

The first substrate 42a includes a conducting layer 44a and an isolating layer 46a. The conducting layer 44a of the first substrate 42a is structured to provide a third DC− area 48a which is connected to the first DC− area 30a and a traversing conducting post 50. The second substrate 42b includes a conducting layer 44b and an isolating layer 46b. The conducting layer 44b of the second substrate 42b is structured to provide a fourth DC− area 48b which is connected to the second DC− area 30b and the traversing conducting post 50.

The traversing conducting post 50 is used for connecting the third DC− area 48a and the fourth DC− area 48b to the intermediate DC− area 32 of the intermediate conducting layer 24. In such a way, the first DC− area 30a is connected via the first substrate 42a and the traversing conducting post 50 with the intermediate DC− area 32 and the second DC− area 30b is connected via the second substrate 42b and the traversing conducting post 50 with the intermediate DC− area 32.

The traversing conducting post 50 runs through the multilayer circuit 18 and/or traverses the multilayer circuit 18 between the first substrate 42a and the second substrate 42b. The traversing conducting post 50 runs through the first conducting layer 20a and in particular the AC area 28a without being connected to them and/or the traversing conducting post 50 runs through the second conducting layer 20b and in particular the AC area 28b without being connected to them. The traversing conducting post 50 runs through the first isolating layer 22a and the second isolating layer 22b. The traversing conducting post 50 runs through the intermediate layer 24 and is connected to the intermediate DC− area 32 and is disconnected from the intermediate AC area 34. The traversing conducting post 50 is connected to the intermediate DC− area 32 inside multilayer circuit board 18.

The traversing conducting post 50 is arranged between the first semiconductor chip T1 and the second semiconductor chip T2 and is arranged between the third semiconductor chip T3 and the fourth semiconductor chip T4. This may be seen with respect to a direction in which the chips T1 and T2 as well as T3 and D4 are arranged.

The traversing conducting post 50 is connected to the third DC− area 48a of the first substrate 42a, which is connected via a first conducting post 52a with the first DC− area 30a. The traversing conducting post 50 is also connected to the fourth DC− area 48b of the second substrate 42b, which is connected via a second conducting post 50 with the second DC− area 30b.

The first conducting post 52a is arranged besides the second semiconductor chip T2 opposite to the traversing conducting post 50 and the second conducting post 52b is arranged besides the fourth semiconductor chip T4 opposite to the traversing conducting post 50. In such a way, two current loops for the DC− current are formed around the semiconductor chips T2, T4.

It may be that the first substrate 42a includes a further conducting layer 54a and/or that the second substrate 42b includes a further conducting layer 54b. 54a/54b is thermal conducting layer but not electronic conducting layer

The semiconductor module 10 may further include a first cooling element 56a and a second cooling element 56b, which are arranged oppositely to each other with respect to the multilayer circuit board 18. The first cooling element 56a is bonded or otherwise attached to backsides of the semiconductor chips T1 and T2. The second cooling element 56b is bonded or otherwise attached to backsides of the semiconductor chips T3 and T4. The cooling elements 56a, 56b may be any kind of cooling element and/or may be based on air and water cooling.

For increasing the mechanical stability and improving the cooling performance of the power semiconductor module 10, spacers 48 may be provided, which are arranged between the multilayer circuit board 18 and the substrates 42a, 42b. Each of the spacers 48 may be a post or bar, which is in contact with the multilayer circuit board 18 and one of the substrates 42a, 42b. The spacers 48 may be made of an electrically isolating material with good thermal conducting properties. For example, the heat conducting coefficient of the spacers 48 may be higher than the one of the semiconductor chips T1, T2, T3, T4.

As an example, the spacers 48 are bonded or otherwise attached to the outer conducting layers 20a, 20b of the multilayer circuit board 18, for example to the AC areas 28a, 28b, and to the conducting layers 44a, 44b of the substrates 42a, 42b.

Due to the design as shown in FIG. 2 with the DC− terminal between and close to the DC+ areas 26 and the DC− areas 30 and the small current loops around the semiconductor chips T2, T4, the stray inductances 16a for the power loops are reduced. Due to the intermediate AC area 34 between the DC− areas 30a, 30b, also the stray inductances 16c for the AC side are reduced in this way.

Furthermore, the symmetric layout for the paralleled power semiconductor chips T1, T2, T3 and T4 results in a good current balance. The power loop inductance for the power semiconductor chips T1, T3 is nearly the same as for the power semiconductor chips T2, T4.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art and practicing the claimed invention, from a study of the drawings, the disclosure, and the appended claims. In the claims, the word “comprising” does not exclude other elements or steps, and the indefinite article “a” or “an” does not exclude a plurality. A single processor or controller or other unit may fulfill the functions of several items recited in the claims. The mere fact that certain measures are recited in mutually different dependent claims does not indicate that a combination of these measures cannot be used to advantage. Any reference signs in the claims should not be construed as limiting the scope.

Modifications and variations can be made to the embodiments illustrated or described herein without departing from the scope and spirit of the invention as set forth in the appended claims. In the claims, reference characters corresponding to elements recited in the detailed description and the drawings may be recited. Such reference characters are enclosed within parentheses and are provided as an aid for reference to example embodiments described in the detailed description and the drawings. Such reference characters are provided for convenience only and have no effect on the scope of the claims. In particular, such reference characters are not intended to limit the claims to the particular example embodiments described in the detailed description and the drawings.

### LIST OF REFERENCE SYMBOLS

10 power semiconductor module
T1 first semiconductor chip
T2 second semiconductor chip
T3 third semiconductor chip
T4 fourth semiconductor chip
DC+DC+ terminal
DC− DC− terminal
AC AC terminal
12 power electrode
14 control electrode
16a stray inductance
16b stray inductance
16c stray inductance
18 multilayer circuit board
20a first outer conducting layer
20b second outer conducting layer
22a first isolating layer
22b second isolating layer
24 intermediate conducting layer
26a first DC+ area
26b second DC+ area
28a first AC area
28b second AC area
30a first DC− area
30b second DC− area
32 intermediate DC− area
34 intermediate AC area
36 through via
38 first small side
40 second small side
42a first substrate
42b second substrate
44a conducting layer
44b conducting layer
46a isolating layer
46b isolating layer
48a third DC− area
48b fourth DC− area
50 traversing conducting post
52a first conducting post
52b second conducting post
54a thermal conductive layer is better
54b thermal conductive layer is better
56a first cooling element
56b second cooling element
58 spacer

1-15: (canceled)

16. A power semiconductor module (10), comprising:
a multilayer circuit board (18) comprising a first outer conducting layer (20a), a first isolating layer (22a), an intermediate conducting layer (24), a second isolating layer (22b), and a second outer conducting layer (20b);
a first semiconductor chip (T1) and a second semiconductor chip (T2) bonded to the first outer conducting layer (20a);
a third semiconductor chip (T3) and a fourth semiconductor chip (T4) bonded to the second outer conducting layer (20b);
a first substrate (42a) attached to the first semiconductor chip (T1) and the second semiconductor chip (T2);
a second substrate (42b) attached to the third semiconductor chip (T3) and the fourth semiconductor chip (T4),
wherein
the first outer conducting layer (20a) is structured into a first DC+ area (26a), a first AC area (28a), and a first DC− area (30a) that interconnect the first semiconductor chip (T1) and the second semiconductor chip (T2) into a first half-bridge,
the second outer conducting layer (20b) is structured into a second DC+ area (26b), a second AC area (28b), and a second DC− area (30b) that interconnect the third semiconductor chip (T3) and the fourth semiconductor chip (T4) into a second half-bridge,
the first DC− area (30a) is connected via the first substrate (42a) and a traversing conducting post (50) with an intermediate DC− area (32) of the intermediate conducting layer (24), and the second DC− area (30b) is connected via the second substrate (42b) and the traversing conducting post (50) with the intermediate DC− area (32), and
the traversing conducting post (50) runs through the multilayer circuit (18) between the first substrate (42a) and the second substrate (42b).

17. The power semiconductor module (10) of claim 16, wherein:
the traversing conducting post (50) is arranged between the first semiconductor chip (T1) and the second semiconductor chip (T2); and
the traversing conducting post (50) is arranged between the third semiconductor chip (T3) and the fourth semiconductor chip (T4).

18. The power semiconductor module (10) of claim 16, wherein the traversing conducting post (50) is connected to the intermediate DC− area (32) inside the multilayer circuit board (18).

19. The power semiconductor module (10) of claim 16, wherein:
the first substrate (42a) comprises a conducting layer (44a) and an isolating layer (46a);
the conducting layer (44a) of the first substrate (42a) is structured to provide a third DC− area (48a) that is connected to the first DC− area (30a) and the traversing conducting post (50);
the second substrate (42b) comprises a conducting layer (44b) and an isolating layer (46b); and
the conducting layer (44b) of the second substrate (42b) is structured to provide a fourth DC− area (48b) that is connected to the second DC− area (30b) and the traversing conducting post (50).

20. The power semiconductor module (10) of claim 16, wherein:
the traversing conducting post (50) is connected to a third DC− area (48a) of the first substrate (42a), and the third DC− area (48a) is connected to the first DC− area (30a);
the first DC− area (30a) and the third DC− area (48a) are connected via a first conducting post (52a);
the traversing conducting post (50) is connected to a fourth DC− area (48b) of the second substrate (42b), and the fourth DC− area (48b) is connected to the second DC− area (30b); and
the second DC− area (30b) and the fourth DC− area (48b) are connected via a second conducting post (52b).

21. The power semiconductor module (10) of claim 20, wherein:
the first conducting post (52a) is arranged besides the second semiconductor chip (T2) opposite to the traversing conducting post (50); and
the second conducting post (52b) is arranged besides the fourth semiconductor chip (T4) opposite to the traversing conducting post (50).

22. The power semiconductor module (10) of claim 16, wherein one or more of:
the intermediate DC− area (32) is arranged between the first DC+ area (26a) and the second DC+ area (26b);
the intermediate DC− area (32) is arranged between the first AC area (28a) and the second AC area (28b); and
the intermediate DC− area (32) is arranged between the first semiconductor chip (T1) and the third semiconductor chip (T3).

23. The power semiconductor module (10) of claim 16, wherein one or more of:
the first AC area (28a) and the second AC area (28b) are connected to an intermediate AC area (34) of the intermediate conducting layer (24);
the intermediate AC area (34) is arranged between the first DC− area (30a) and the second DC− area (30b); and
the intermediate AC area (34) is arranged between the second semiconductor chip (T2) and the fourth semiconductor chip (T4).

24. The power semiconductor module (10) of claim 23, wherein an AC terminal (AC) is connected to the intermediate AC area (34).

25. The power semiconductor module (10) of claim 16, wherein:
a DC+ terminal (DC+) is connected to the first DC+ area (26a) and the second DC+ area (26b); and
a DC− terminal (DC−) is connected to the intermediate DC− area (32).

26. The power semiconductor module (10) of claim 25, wherein:
the DC+ terminal (DC+) and the DC− terminal (DC−) are arranged at a first side (38) of the power semiconductor module (10); and
an AC terminal (AC) connected to the first AC area (28a) and the second AC area (28b) is arranged on a second side (40) of the power semiconductor module (10), which is opposite to the first side (38).

27. The power semiconductor module (10) of claim 16, wherein:
the first semiconductor chip (T1) and the third semiconductor chip (T3) are arranged opposite each other with respect to the multilayer circuit board (18); and
the second semiconductor chip (T2) and the fourth semiconductor (T4) chip are arranged opposite each other with respect to the multilayer circuit board (18).

28. The power semiconductor module (10) of claim 16, wherein:
the first DC+ area (26) and the second DC+ area (26) are arranged opposite each other with respect to the multilayer circuit board (18);
the first AC area (28) and the second AC area (28) are arranged opposite each other with respect to the multilayer circuit board (18); and
the first DC− area (30) and the second DC− area (30) are arranged opposite each other with respect to the multilayer circuit board (18).

29. The power semiconductor module (10) of claim 16 wherein:
the first semiconductor chip (T1) and the second semiconductor chip (T2) are arranged in a row along the first DC+ area (26), the first AC area (28) and the first DC− area (30); and
the third semiconductor chip (T3) and the fourth semiconductor chip (T4) are arranged in a row along the second DC+ area (26), the second AC area (28) and the second DC− area (30).

30. The power semiconductor module (10) of claim 16, wherein the first semiconductor chip (T1), the second semiconductor chip (T2), the third semiconductor chip (T3) and the fourth semiconductor chip (T4) are based on a wide bandgap semiconductor material.
